(19) United States
(12) Patent Application Publication
(10) Pub. No.: US 2015/0377937 A1
(43) Pub. Date: Dec. 31, 2015

(54) Calculating Power Consumption of Electonic Devices

(71) Applicant: ST-ERICSSON SA, Plan-les-Ouates (CH)

(72) Inventors: Nicolas LAFARGUE, Montbonnot-Saint-Martin (FR); Thomas ALOFS, Grenoble (FR)

(73) Assignee: ST-Ericsson SA, Plan-les-Ouates (CH)

(21) Appl. No.: 14/769,528

(22) PCT Filed: Feb. 18, 2014
(86) PCT No.: PCT/EP2014/053148

§ 371 Date: Aug. 21, 2015

(30) Foreign Application Priority Data
Mar. 22, 2013 (EP) 13368012.4

(51) Int. Cl. G01R 21/133

(52) U.S. Cl. CPC G01R 21/133

(57) ABSTRACT

A power consumption measurement method for operating an electronic component during an interval of time includes: logging power states that the component adopts during the interval, interrogating the log to determine the amount of time that the component spent in each power state during interval, and multiplying the rated power consumption for each state by the amount of time spent in each respective state. The power consumptions for each of the states are summed to determine a total power consumption of the component during the interval. Logging the power states may be achieved by counting command line instructions of different types, thus identify the beginning and end of each power state, during the interval. The method may be used to measure and/or benchmark the actual power consumption of a DDR RAM module. An apparatus for carrying out the method is also disclosed.

This invention relates to a method and apparatus for calculating the power consumption of electronic components, devices or systems. More particularly, but without limitation to the same, the invention relates to a method and apparatus for benchmarking of Random Access Memory (RAM) power consumption.

May modern electronic devices are powered by batteries, which places restrictions on the amount of power that is available between charges. Miniaturisation of electronic devices, an increases in processing capabilities impose conflicting requirements in terms of power consumption and available battery capacity, so a great deal of effort is nowadays spent on reducing the power consumption of the various components of electronic devices.

To ensure that individual components of electronic devices do not consume an unfair or disproportionate amount of available power, it has become commonplace to impose so-called “power budgets” for individual components of electronic systems. Moreover, the consumption of power has to be minimised to the greatest possible extent to conserve power wherever possible, which has led to the routine implementation of so-called “standby”, “power-down”, “hibernate” states in many of the components of electronic devices. Moreover, to enable designers to correctly specify components and to design electronic devices, OEMs are encouraged, or mandated, to provide data sheets specifying the power consumption of OEM components in each available energy state. This detailed information can be used to estimate a theoretical power consumption of an electronic system made up of a number of components, in simulated operational conditions.

Known methods involve calculating a theoretical overall power consumption by computational methods. For example, a device has two states, namely “standby” and “active”, and the average power consumption of the device in each state is known from the OEM's data sheet. A simulation of a particular process estimates that the device will be in the “standby” state for 40% of the process, and the “active” state for the remaining 60% of the time. For a process taking a known amount of time, the theoretical power consumption for the process can be readily calculated. Of course, with a view to reducing power consumption, most devices have more than two states, for example, in the case of a hard disk drive, a “hibernate” state in which the drive is inactive and only it's I/O systems are active to detect a wake up signal, a “wake up” state, whereby the device's firmware is woken from the hibernate state, a “spin-up” state whereby the drive's motor is used to accelerate the disk, an “idle” state, whereby the disk is up to speed, but is not being written to, or read from; “read” and “write” active states, a “spin-down” state whereby the drive transitions from active to “hibernate” etc. With the power consumption for each available state for each device known, it is possible, albeit quite involved, to model the power consumption of complex electronic devices in various simplified model situations.

In one specific example, which is the primary focus of this invention, there exists a need for benchmarking the power consumption of RAM modules, which are notoriously power-hungry components of electronic systems. As RAM technology advances, more and more possible states are being implemented to conserve power, but which, at the same time, make it increasingly difficult to model actual power consumption.

The known system of power budget benchmarking suffers the disadvantage of being based on simplified models and presupposes that the components in question will adopt their various states for known intervals. However, in real situations, the theoretical power consumption rarely matches the actual power consumption because the simulations are rarely able to anticipate events, such as I/O conflicts or data collisions, which regularly occur in real systems and which are dealt with by conflict resolution routines, but which may not be adequately modelled in the simulation. A need therefore arises for an improved and/or alternative benchmarking system that addresses one or more of the above problems.

According a first aspect of the invention, there is provided a power benchmarking method comprising the steps of operating an electronic component during an interval of time and logging the power states that the component adopts during the said interval, interrogating the log to determine the total amount of time the component spent in each power state and multiplying the rated power consumption for each state by the time it spent in each respective state.

Suitably, the total power consumption during the said interval can be calculated by summing the power consumptions for each of the states.

The rated power consumptions for each state may be determinable, for example, by experimentation, or by consulting the OEM data sheet for the component.

The actual power consumption of a system comprising a number of components can be similarly ascertained by carrying out the method for each component and summing the power consumptions of each component to yield a total power consumption for the system during the said interval.

The method may be performed in hardware and/or software. Suitably, hardware may be used for making measurements, whilst software could be used for reading the log and calculating the overall power consumption.

A second aspect of the invention provides a power benchmarking apparatus comprising means for determining the instantaneous power state of an electronic component, the instantaneous power state being any one of a number of possible power states of the electronic component, means for triggering the means for determining at intervals to detect the instantaneous power state at different points in time, means for logging the detected instantaneous power states over an interval of time, means for accessing the log to determine the total amount of time the electronic component spent in each of its possible power state during the said interval of time.

The apparatus suitably further comprises means for calculating the power consumption in each state by multiplying the rated power consumption of the electronic component for each state by the total time it spent in each respective state over the said interval of time. Suitably, apparatus comprises means for calculating the total power consumption over the interval of time, said means comprising means for summing the calculated power consumptions for each state over the said interval.

Thus, the invention suitably provides a means for measuring and/or monitoring the actual power consumption of an electronic component. The invention thus differs from the prior art inasmuch as it measures the actual power consumption, rather than estimating it based on simulation data.

The power benchmarking apparatus comprises means for determining the instantaneous power state of an electronic component, which, in the case of a RAM module, may comprise dedicated hardware embedded on any one or more of: the System On Chip (SOC); the external memory interface; the memory die; the system's Central Processing Unit (CPU); an external memory interface where the commands are readily available; or in an interface between the memory module; and the CPU. In one possible embodiment of the invention, the dedicated hardware may be incorporated into an adaptor module interposed between the memory module's socket and the memory module itself.

In the case of a RAM module, the dedicated hardware suitably comprises an interface operatively connected to the controller of the memory array and/or the memory's registers, and comprises a summing or integrating circuit adapted to count the number of memory state requests.

In the case of low-power DDRx RAM module, the instantaneous power states may be any one of more of the group comprising: deep power down (DPD), idle, idle power-down, self-refresh, active power down, active and idle power down. The dedicated hardware suitably interfaces with the system clock, or the component's internal clock to establish a suitable time base based on clock cycle counting. By such a configuration, the dedicated hardware, is capable of detecting commands within the RAM module identifying the beginning and end of each memory operation state at intervals, e.g. at integer multiples of clock cycles, thus enabling the time that each part of the memory array is in each state to be determined. The memory commands suitable comprise any one or more of the group comprising: active (ACT), pre-charge (PRE), auto refresh (AREF), self-refresh (SREF), READ, WRITE, etc.

The dedicated hardware comprises means for triggering the means for determining at intervals to detect the instantaneous power state at different points in time. As previously described, the trigger signals could be derived from internal memory commands controlling the transition of individual memory cells or units between different energy states.

The apparatus comprises a means for logging the detected instantaneous power states over an interval of time, which suitably takes the form of a storage device that can be internal to, or external of, the component being tested. Suitably, the dedicated hardware comprises an interface for transmitting data, either at the end of a data collection period, or as the data is collected, to a suitable memory device upon which a data log is stored.

The data log is accessible by software to enable a calculation to be carried out based on the logged data to determine the actual power consumption over the interval of time, i.e. the test/measurement routine.

Various embodiments of the invention shall now be described, by way of example only, with reference to the accompanying drawings in which:

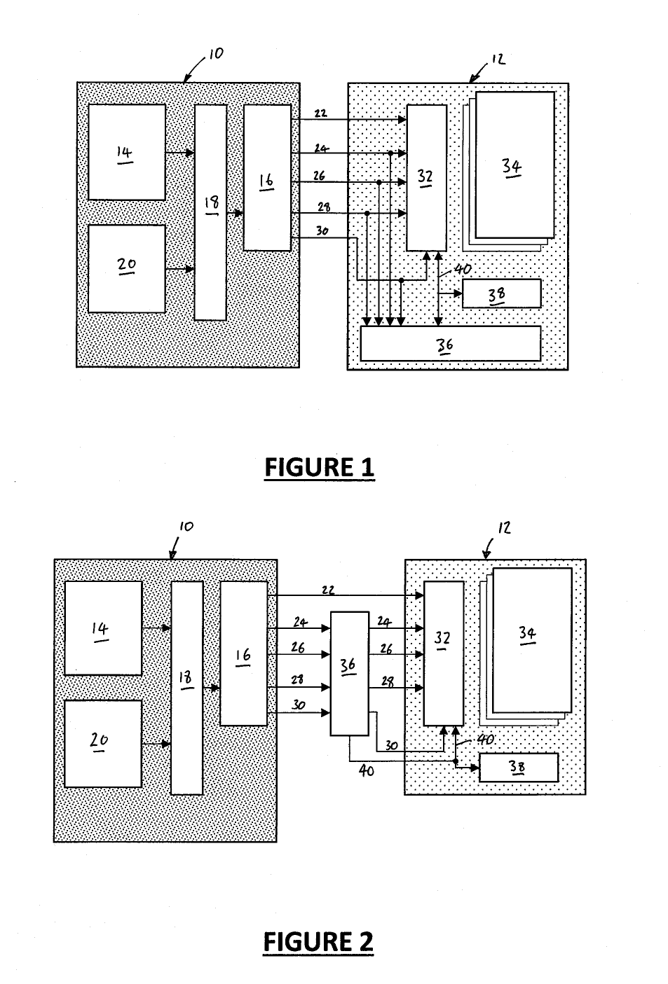

FIGS. 1, 2 and 3 are schematic diagrams showing, respectively, an on-die, an off-die and an adaptor-based implementation of the invention for a DDR RAM module; and

FIG. 4 is a schematic table showing how energy consumption can be calculated.

In FIG. 1, a System on Chip (SOC) device 10 is operatively connected to a DDR RAM module 12. The SOC 10 comprises a Central Processing Unit (CPU) 14 that addresses the RAM module 12 via an external memory interface 16 connected to the system bus 18, which in-turn, provides an interface for other components and input/output (I/O) ports 20 of the SOC 10. The external memory interface 16 addresses the RAM module 12 via a number of conductors, which have been simplified in the drawings to indicate a clock line 22 providing a synchronous clock for the RAM module 12 with that of the external memory interface 16, a command line 24, a memory address interface 26 (the command line 24 and memory address interface 26 are typically shared, e.g. in the case of DDR memory), a data line 28 and a chip select line 30. These lines, 22, 24, 26, 28, 30 interface with a control logic module 32 of the DDR memory module 12 to operate, in use, the memory array 34. Connected in parallel with the lines 22, 24, 26, 28, 30 is a DIAgnosis of external Memory Power consumption (DIAP) module 36 that is formed integrally on the RAM die, which also interfaces with the RAM's registers 38 via further lines 40.

The CPU 14 thus executes commands and performs read/write operations on the RAM module 12 in a known manner, whilst the DIAP module 36 able to determine line activity simultaneously. Because the direct connections between the external memory interface 16 and the RAM module 12 remain intact, the DIAP module 36 is effectively invisible to the SOC 10 and the RAM module 12, thus neither slowing, nor interfering with, the operation of either. The invisibility of the DIAP module 36 to the system 10, 12 is an important consideration in benchmarking as the system 10, 12 needs to perform, under test conditions, i.e. with the DIAP module 36 active, in the same, or substantially the same manner, as under normal operating conditions, i.e. with the DIAP module 36 inactive, or not present at all.

To perform a benchmarking operation, the system 10, 12 is set to execute a desired function, for example, to execute an application, and the DIAP module 36 is switched on. After a predetermined number of clock cycles 22 or upon detection of a predetermined event on the command and/or address line bus, which can be set via DIAP-addressing software, the DIAP module 36 deactivates. During the test interval, the DIAP module counts the number of memory commands, and records these in an internal log. After completion of the test, the DIAP-interface software can recover the DIAP datasheet via the data line 28 for analysis.

In FIG. 4, an exemplary log is shown 42 is shown, in which the detected memory states are recorded during the test interval, in the illustrated example, a test lasting for 38 clock cycles, which of course, in practice would be much longer. During the test, the DIAP is configured to detect commands on line 24 corresponding to different memory addresses on line 26, indicating transitions from one memory state to another for each memory address. The DIAP module 36 is synchronized with a clock to establish a time base, in the example of FIG. 1, the external memory interface clock 16, but this could be an internal memory clock, or indeed a dedicated clock on the DIAP module 36 itself. The DIAP module 36 is thus able to populate a table indicating the number of times 44 each memory has been in any one of a number of states 46 and for how long 48 (in multiples of clock cycles).

For each state 46, the amount of time, t, each memory address has been in that state can be calculated by summing the count 44 multiplied by the time 48. The rated energy requirement E for each interval of memory state activity is known from the OEM's data sheet for the RAM module 12, and this is multiplied by the t values to calculate the energy consumption of the RAM module in each state P. The t and P values can then be summed to determine the total test duration and the total power consumed, which can be divided to yield an average power consumption (energy usage per unit time) for the system under the specified test conditions. This process can be repeated for different durations, and under different loading conditions to determine the actual power requirements of the RAM module 12 under various actual usage conditions.

FIG. 2 is an alternative embodiment of the invention in which the DIAP module 36 is located off the RAM die, for example, in a dedicated hardware module that an OEM, designer or testing laboratory can connect to the RAM module 12 for benchmarking purposes. It will be apparent that the connections are operation of the embodiment shown in FIG. 2 are systematically identical with that shown in FIG. 1, except that it is not necessary for the RAM OEM to integrate the DIAP module in actual production dies, but can rather produce DIAP and non-DIAP versions of the RAM module without having to re-tool the main RAM die.

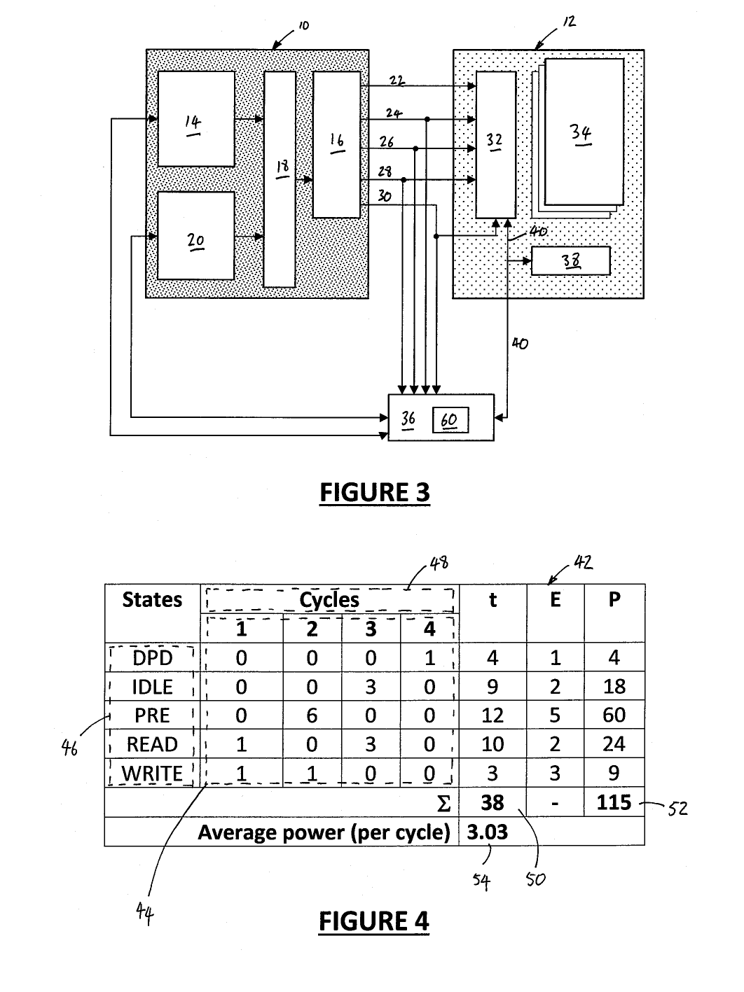

FIG. 3 shows a yet further embodiment of the invention in which the DIAP module 36 is provided in an adapter that interfaces with the SOC 10 via an I/O port 20. Such an implementation may take the form of a physical adapter placed between the RAM module 12 and a socket therefor on the SOC backplane. In this embodiment, the DIAP module 36 detects memory state commands and durations as previously described, but buffers the data log on a dedicated, supplementary RAM module 60 located on it. The DIAP module 36, in this case, additionally comprises I/O functionality to enable the data log to be read from and/or written to by an interface 20 of the SOC 10, for example, a USB, SATA or PCI interface of the SOC 10.

In a yet further possible embodiment of the invention, the configuration of FIG. 3 could be modified such that the DIAP module is configured to observe the memory bus using at the top level connections. Moreover, in a preferred implementation sees module 36 as part of the SoC 10, in which case, the external memory bus is observed from within the SoC level: the module 36 is thus connected to the interconnect 18 for configuration and data retrieval, rather than having a direct connection to module 14 or 20.

The invention is not restricted to the details of the foregoing embodiments, which are merely exemplary of the invention. For example, the hardware implantation of the DIAP module could be altered without departing from the invention, and the DIAP module, or a method or apparatus according to the invention could be used to benchmark or monitor the power consumption of components other than a RAM module, for example, an interface card, a graphics chip, the CPU etc. Moreover, one or more DIAP modules could be fitted to one or more components simultaneously, or sequentially, to establish a power consumption benchmark for a complex system comprised of a number of components. In addition, the invention need not necessarily be used for benchmarking purposes at the design/testing stages of SOC and/or component development: it could be implemented as part of an overall power management system for use in actual operation of an electronic device, which could be advantageous in managing power consumption, and predicting battery discharge, especially in critical situations, such as in battery-powered medical devices or emergency telecommunication devices.

1. A power consumption measurement method for operating an electronic component during an interval of time, the method comprising:
logging power states that the electronic component adopts during the said interval of time in a log;
interrogating the log to determine a total amount of time that the electronic component spent in each of the power states during said interval; and
multiplying a rated power consumption for each of the power states by the respective total amount of time spent in each respective power state to obtain power consumptions for the power states, respectively.

2. The method of claim 1, further comprising summing the power consumptions to determine a total power consumption of the electronic component during the said interval of time.

3. The method of claim 1, wherein the logging of the power states comprises counting command line instructions of different types during the said interval of time.

4. The method of claim 3, wherein the command line instructions are used to identify beginning and end of each of the power states.

5. The method of claim 1, further comprising logging a start time and an end time of each of the power states in clock cycles.

6. The method of claim 5, wherein the clock cycles comprise any one or more of the group comprising: system clock cycles external to the component; clock cycles of the component; and dedicated interval-determining clock cycles.

7. The method of claim 1, wherein the electronic component comprises a RAM module.

8. The method of claim 7, further comprising logging detected memory states adopted during the interval of time, the detected memory states corresponding to different memory addresses detected on a memory address interface line indicating transitions from one memory state to another for each memory address.

9. A power consumption benchmarking method, wherein a system comprising a RAM module is set to execute a function, wherein the method of claim 7 is initiated, a number of memory commands and corresponding durations during the said interval of time are logged and the method is terminated after the said interval of time.

10. The power consumption benchmarking method as claimed in claim 9, further comprising:
multiplying the product of the number of memory commands and their durations with the rated power consumption of the RAM module to determine an actual energy consumption of the RAM module during the said interval.

11. A method of determining a power consumption of a system comprising a number of components by carrying out the method of claim 1 on a number of the components of the system simultaneously or sequentially.

12. An apparatus for measuring the power consumption of an electronic component, the apparatus comprising:
means for determining an instantaneous power state of the electronic component, the instantaneous power state being any one of a number of possible power states of the electronic component;
means for triggering the means for determining at intervals to detect the instantaneous power state at different points in time;
means for logging the detected instantaneous power state over an interval of time, in a log; and
means for accessing the log to determine a total amount of time that the electronic component spent in each of the possible power states during said interval of time.

13. The apparatus of claim 12, further comprising means for calculating the power consumption in each state configured to multiply a rated power consumption for the electronic component in each of the possible power states by the respective total amount of time.

14. The apparatus of claim 12, wherein the electronic component comprises a RAM module.

15. The apparatus of claim 14, wherein the means for determining the instantaneous power state of the RAM module is operatively connected to a logic controller of the RAM module and is adapted to count command line instructions of different types during said interval of time.

16. The apparatus of claim 14, wherein the means for determining the instantaneous power state of the RAM module is operatively connected to a clock, and wherein the interval of time is determined by a specified number of clock cycles.

17. The apparatus of claim 14, wherein the means for determining the instantaneous power state comprises any one or more of the group comprising:
hardware embedded on a memory die;
hardware within a system's Central Processing Unit;
hardware in an interface between a memory module and a system's Central Processing Unit; and
hardware incorporated into an adaptor interposed between a memory module's socket and a memory module therefor.

18. A System on Chip device operatively connected to a DDR RAM module, the System on Chip device comprising:
a Central Processing Unit configured to address the DDR RAM module via an external memory interface connected to a system bus;
an external memory interface adapted to address the DDR RAM module via
a plurality of conductors, the plurality of conductors comprising, at least following lines: a clock line providing a synchronous clock for the DDR RAM module with that of the Central Processing Unit; a command line; a memory address interface line; a data line; and a chip select line, said lines interfacing with a control logic module of the DDR RAM module to operate, in use, a memory array of the DDR RAM module, and
a DIAgnosis of external Memory Power consumption module operatively connected in parallel with the said lines and configured to interface with a register of the DDR RAM module,
wherein, when the Central Processing Unit, in use, executes commands on the DDR RAM module, the DIAgnosis of external Memory Power Consumption module is configured to detect and record line activity.
